(19) United States
(12) Patent Application Publication
(10) Pub. No.: US 2024/0153845 A1
(43) Pub. Date: May 9, 2024

(54) INTEGRATED CIRCUIT DEVICE WITH THERMAL DISSIPATING PACKAGE

(71) Applicant: GUANGZHOU NEOGENE THERMAL MANAGEMENT TECHNOLOGY CO., LTD., GUANGZHOU (CN)

(72) Inventor: JEN-SHYAN CHEN, GUANGZHOU (CN)

(21) Appl. No.: 18/360,206

(22) Filed: Jul. 27, 2023

(30) Foreign Application Priority Data
Nov. 8, 2022 (CN) 202222972384.6
Feb. 17, 2023 (CN) 202310131381.6

(51) Int. Cl. H01L 23/427; H01L 23/40; H01L 25/065; H05K 7/20

(52) U.S. Cl. CPC H01L 23/427; H01L 23/4006; H01L 25/0655; H05K 7/20254; H01L 2023/4043; H01L 2023/4062

(57) ABSTRACT

An integrated circuit device with thermal dissipating package comprises a circuit board, a chip and a three-dimensional vapor chamber device. The chip is configured on an upper board surface of the circuit board. The three-dimensional vapor chamber device comprises an upper cover and a bottom cover. The upper cover has a base plate and a tube. The base plate has an opening and an upper outer surface. An airtight cavity is formed from the tubular cavity of the tube when the bottom cover is sealed to the upper cover. The bottom groove of the bottom cover is configured to accommodate the chip. The chip surface is contacted with the bottom groove surface. The semi-open case has an inlet and an outlet and is coupled to the bottom cover to form a heat-exchanging chamber. The inlet and outlet are connected to the heat-exchanging chamber.

### BACKGROUND OF THE INVENTION

### 1. Field of the Invention

The present invention relates to an integrated circuit (IC) device, and more particularly, to an integrated circuit device with thermal dissipating package.

### 2. Description of the Prior Art

Usually, the heat generation of a semiconductor chip would increase greatly with the computing speed thereof. If the heat generated by the chip cannot be dissipated effectively, it would cause the chip to overheat and then work in the underclocking state or even break down. Due to the popularity of electric vehicles, the demand for the fast charging and discharging of power batteries and the demand for heat dissipation of in-vehicle insulated gate bipolar transistor (IGBT) power chips have increased dramatically, and the chips with high computing power are also required for self-driving functions. The central processing unit (CPU) power of data center servers for cloud computing has continuously increased. Under the aforementioned conditions, the power of a single packaged integrated circuit (IC) has reached 500 W or 700 W, and there will be requirements for more than 1000 W of an integrated circuit.

It is known that the heat dissipation technology for semiconductor chips usually uses an external heat dissipator attached to the package case of the chip, so as to transfer the heat generated by the chip to the heat dissipator and then dissipate the heat by air cooling or water cooling. In the prior art, the packaged IC device and the heat dissipator are two separate components and many interface thermal resistances exist between the two components. Once the power of the IC is high, a slight increase of interface thermal resistance would cause a large temperature rise in the chip.

Therefore, in order to solve the problems of the prior art, it is necessary to improve the chip package and reduce the excess interface and thermal resistance between the IC device and heat dissipator to break the power limit of a high computing capacity IC.

### SUMMARY OF THE INVENTION

Therefore, the present invention provides an integrated circuit device with thermal dissipating package to solve the problems of the prior art.

The present invention provides an integrated circuit device with thermal dissipating package, which comprises a circuit board, a chip and a three-dimensional vapor chamber device. The circuit board has an upper board surface. The chip is configured on the upper board surface of the circuit board. The chip has a chip surface. The three-dimensional vapor chamber device comprises an upper cover and a bottom cover. The upper cover comprises a base plate and a tube. The base plate has an opening hole, an upper outer surface and an upper internal surface. The tube has a tubular cavity and a tubular internal surface. The tube is configured on the upper outer surface and located above the opening hole and extended outwardly from the upper outer surface. The bottom cover corresponding to the upper cover has a bottom groove. The bottom groove has a bottom groove surface. An airtight cavity is formed from the tubular cavity when the bottom cover is sealed to the upper cover. The bottom groove is configured to accommodate the chip. The chip surface of the chip is contacted with the bottom groove surface of the bottom groove.

Wherein, the integrated circuit device with thermal dissipating package of the present invention further comprises a semi-open case. The semi-open case has an inlet and an outlet. The semi-open case is coupled to the bottom cover of the three-dimensional vapor chamber device to form a heat-exchanging chamber and the upper cover is configured in the heat-exchanging chamber. The inlet and the outlet are connected to the heat-exchanging chamber. The bottom groove is configured to accommodate the circuit board with the chip. The circuit board has a plurality of locking holes, and the circuit board with the chip is locked to the bottom groove surface of the bottom groove by a plurality of screws.

Wherein, a cold liquid fluid is configured in the heat-exchanging chamber, the inlet and the outlet, and the cold liquid fluid is selected from the group consisting of water, acetone, ammonia, methanol, tetrachloroethane, and hydrofluorocarbon chemical refrigerants.

Wherein, the bottom cover has a plurality of grooves, and a groove rib is formed between the grooves, the groove rib has a rib surface, and each of the grooves has a groove internal surface and a groove cavity.

Wherein, the integrated circuit device with thermal dissipating package of the present invention further comprises a porous wick structure, the bottom cover has a bottom internal surface, the porous wick structure is continuously disposed on the upper internal surface, the bottom internal surface, the tubular internal surface, the rib surface of the groove rib and the groove internal surfaces.

Wherein, the three-dimensional vapor chamber device further comprises a plurality of heat dissipation fins, the tube further comprises a condenser area, and the heat dissipation fins are coupled to the condenser area of the tube.

Wherein, the porous wick structure is disposed by pre-laying a copper-containing powder on the upper internal surface, the bottom internal surface, the tubular internal surface, the rib surface and the groove internal surfaces, and after the heat dissipation fins are disposed on the condenser area of the tube, the porous wick structure is continuously disposed on the upper internal surface, the bottom internal surface, the tubular internal surface, the rib surface and the groove internal surfaces and the heat dissipation fins are coupled to the condenser area simultaneously by the same sintering process.

Wherein, the tube further has a top end having a sealed structure, the base plate further has a base cavity, and the airtight cavity is formed from the base cavity and the tubular cavity when the bottom cover is sealed to the upper cover.

Wherein, the sealed structure is formed by pre-setting a liquid injection port at the top end, and injecting the working fluid into the airtight cavity through the liquid injection port, and then sealing the liquid injection port.

The present invention provides another integrated circuit device with thermal dissipating package, which comprises a circuit board, a plurality of chips, a plurality of three-dimensional vapor chamber devices and a semi-open case. The circuit board has an upper board surface. The plurality of chips is configured on the upper board surface of the circuit board, and each of the chips has a chip surface. The plurality of three-dimensional vapor chamber devices comprises a plurality of upper covers and a bottom cover. Each of upper covers comprises a base plate and a tube. The base plate has an opening hole, an upper outer surface and an upper internal surface. The tube has a tubular cavity and a tubular internal surface. The tube is configured on the upper outer surface and located above the opening hole and extended outwardly from the upper outer surface. The bottom cover corresponding to the upper covers has a bottom groove. The bottom groove has a bottom groove surface. An airtight cavity is formed from the corresponding tubular cavity when the bottom cover is sealed to the upper covers. The bottom groove is configured to accommodate the chips. Each of the chip surfaces is contacted with the bottom groove surface of the bottom groove. In practice, the tube can be directly sealed to the base plate, and the airtight cavity can be formed only by the tube cavity.

In summary, the present invention provides an integrated circuit device with thermal dissipating package, integrating the circuit board with the chip and the heat dissipator in an integrated circuit device. The integrated circuit device with thermal dissipating package in the present invention can reduce the thermal resistances between the chip and the heat dissipator in the integrated circuit packaging of the prior art by contacting the chip surface with the bottom groove surface of the three-dimensional vapor chamber device. Moreover, by directly contacting with the cold liquid fluid in the heat-exchanging chamber through the condenser area of the three-dimensional vapor chamber device with two-phase flow circulation for heat exchange to enhance the heat dissipation efficiency of the integrated circuit device with thermal dissipating package of the present invention. In addition, the screws in the integrated circuit device with thermal dissipating package of the present invention can fix the circuit board with the chip to the lower case surface. The screws can increase the contact pressure between the chip and the bottom groove surface of the bottom cover in the three-dimensional vapor chamber device, so as to reduce the contact thermal resistance and improve the heat dissipation efficiency of the integrated circuit device. Furthermore, the plurality of grooves of the bottom cover in the integrated circuit device with thermal dissipating package of the present invention can reduce the thermal resistance of heat conduction from the heat source to the porous wick structure disposed on the bottom internal surface of the bottom cover by reducing the heat conduction distance between the porous wick structure disposed on the bottom cover and the heat source, while taking into account the structural strength of the bottom cover, so as to enhance the heat conduction efficiency. Furthermore, the integrated circuit device with thermal dissipating package of the present invention can increase the contact area between the condenser area and the cold liquid fluid through the heat dissipation fins disposed on the tube to enhance the heat dissipation efficiency; and increase the heat exchange efficiency with the cold liquid fluid in the heat-exchanging chamber through the flow disturbance structure disposed on the heat dissipation fins generates mixed flow in the heat-exchanging chamber, so as to increase the heat dissipation efficiency. In the integrated circuit device with thermal dissipating package of the present invention, the plurality of upper covers of the three-dimensional vapor chamber device can be coupled with the same bottom cover to be contacted with the plurality of heat sources or the same heat source, and dissipate heat in the same heat exchanger, so as to enhance the whole heat dissipation efficiency of the present invention. Compared to the prior art, the integrated circuit device with thermal dissipating package of the present invention integrates the circuit board with the chip and the heat dissipator in an integrated circuit device to reduce the redundant interface and thermal resistance between the integrated circuit device and the heat dissipator, so as to enhance the whole heat dissipation efficiency of the integrated circuit device with thermal dissipating package.

### BRIEF DESCRIPTION OF THE APPENDED DRAWINGS

FIG. 1 is a cross-sectional diagram illustrating an integrated circuit device with thermal dissipating package according to an embodiment of the present invention.

FIG. 2 is a cross-sectional diagram illustrating a three-dimensional vapor chamber device in FIG. 1.

FIG. 3 is a cross-sectional diagram illustrating an integrated circuit device with thermal dissipating package according to another embodiment of the present invention.

FIG. 4 is a structural schematic diagram illustrating a heat dissipation fin in FIG. 3.

FIG. 5 is a cross-sectional diagram illustrating an integrated circuit device with thermal dissipating package according to another embodiment of the present invention.

FIG. 6 is a cross-sectional diagram illustrating an integrated circuit device with thermal dissipating package according to another embodiment of the present invention.

FIG. 7 is a cross-sectional diagram illustrating an integrated circuit device with thermal dissipating package according to another embodiment of the present invention.

FIG. 8 is a cross-sectional diagram illustrating an integrated circuit device with thermal dissipating package according to another embodiment of the present invention.

### DETAILED DESCRIPTION OF THE INVENTION

For the sake of the advantages, spirits and features of the present invention can be understood more easily and clearly, the detailed descriptions and discussions will be made later by way of the embodiments and with reference of the diagrams. It is worth noting that these embodiments are merely representative embodiments of the present invention, wherein the specific methods, devices, conditions, materials and the like are not limited to the embodiments of the present invention or corresponding embodiments. Moreover, the devices in the figures are only used to express their corresponding positions and are not drawing according to their actual proportion.

In the description of the presentation, the description with reference to the terms “an embodiment”, “another embodiment” or “part of an embodiment” means that a particular feature, structure, material or characteristic described in connection with the embodiment including in at least one embodiment of the present invention. In the presentation, the schematic representations of the above terms do not necessarily refer to the same embodiment. Furthermore, the particular features, structures, materials or characteristics described may be combined in any suitable manner in one or more embodiments. Furthermore, the indefinite articles “a” and “an” preceding a device or element of the present invention are not limiting on the quantitative requirement (the number of occurrences) of the device or element. Thus, “a” should be read to include one or at least one, and a device or element in the singular also comprises the plural unless the number clearly refers to the singular.

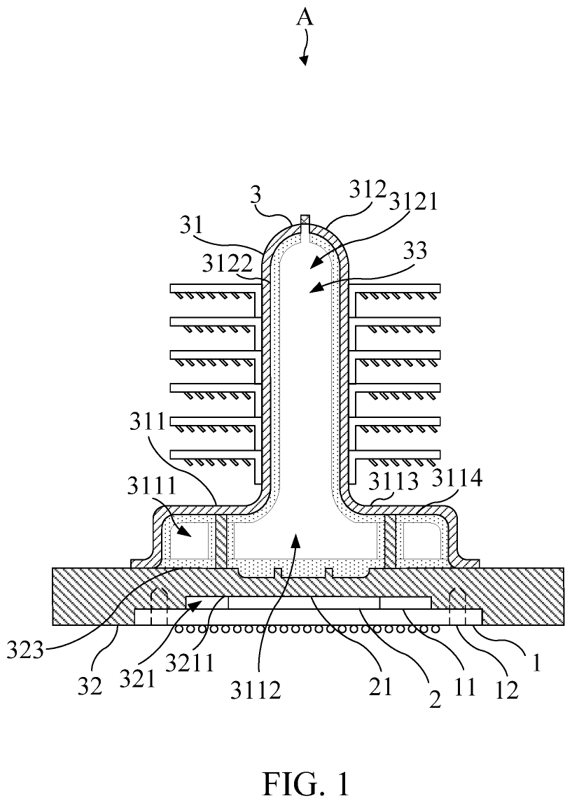

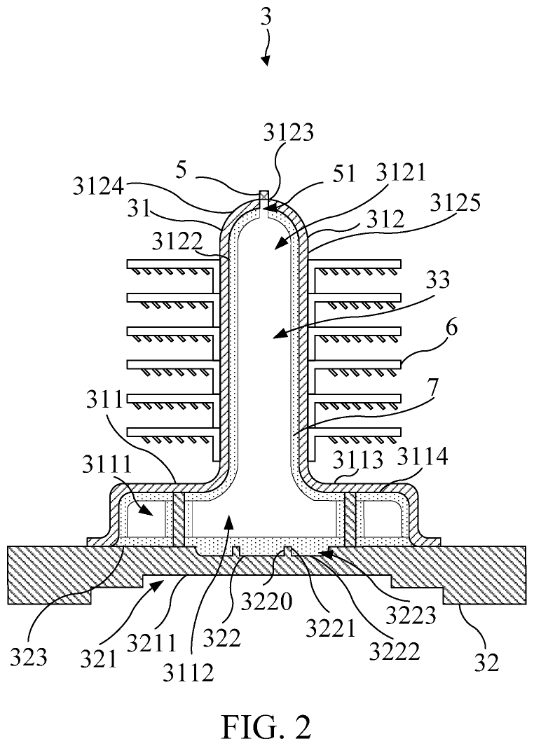

Please refer to FIG. 1 and FIG. 2. FIG. 1 is a cross-sectional diagram illustrating an integrated circuit device A with thermal dissipating package according to an embodiment of the present invention. FIG. 2 is a cross-sectional diagram illustrating a three-dimensional vapor chamber device 3 in FIG. 1. As shown in FIG. 1, the present invention provides an integrated circuit device A with thermal dissipating package, which comprises a circuit board 1, a chip 2 and a three-dimensional vapor chamber device 3. The circuit board 1 has an upper board surface 11. The chip 2 is configured on the upper board surface 11 of the circuit board 1. The chip 2 has a chip surface 21. The three-dimensional vapor chamber device 3 comprises an upper cover 31 and a bottom cover 32. In the present embodiment, the upper cover 31 of the three-dimensional vapor chamber device 3 comprises a base plate 311 and a tube 312. The base plate 311 has a base cavity 3111, an opening hole 3112, an upper outer surface 3113 and an upper internal surface 3114. The tube 312 has a tubular cavity 3121 and a tubular internal surface 3122. The tube 312 is configured on the upper outer surface 3113 and located above the opening hole 3112 and extended outwardly from the upper outer surface 3113. An airtight cavity 33 is formed from the base cavity 3111 and the tubular cavity 3121 when the bottom cover 32 is sealed to the upper cover 31. In practice, the tube 31 can be directly sealed to the base plate 311, and the airtight cavity 33 can be formed only by the tube cavity 3121.

As shown in FIG. 2, the tube 312 further has a top end 3123 having a sealed structure 5. The sealed structure 5 is formed by pre-setting a liquid injection port 51 at the top end 3123, and injecting the working fluid into the airtight cavity 33 through the liquid injection port 51, and then sealing the liquid injection port 51. It should be noted that in the present embodiment, the sealed structure 5 is formed by pre-setting a liquid injection port 51 at the top end 3123, and injecting the working fluid into the airtight cavity 33 through the liquid injection port 51, and then sealing the liquid injection port 51. In practice, the liquid injection port 51 can be sealed by welding, etc. Furthermore, the liquid injection port 51 and the sealed structure 5 of the three-dimensional vapor chamber device 3 in the present invention are located at the top end 3123 of the tube 312, but it is not limited in practice, the liquid injection port 51 and the sealed structure 5 can be set at any position on the tube 312.

In addition, in the present embodiment, the bottom cover 32 of the three-dimensional vapor chamber device 3 corresponding to the upper cover 31 has a bottom groove 321. The bottom groove 321 has a bottom groove surface 3211. The bottom groove 321 is configured to accommodate the chip 2. The chip surface 21 of the chip 2 is contacted with the bottom groove surface 3211 of the bottom groove 321. Furthermore, the bottom groove 321 is configured to accommodate the circuit board 1 with the chip 2. The circuit board 1 has a plurality of locking holes 12, and the circuit board 1 with the chip 2 is locked to the bottom groove surface 3211 of the bottom groove 321 by a plurality of screws (not shown), so the circuit board 1 can be fixed to the bottom cover 32 by the corresponding plurality of screws. The screw locking by the screws can increase the contact pressure between the chip 2 and the bottom groove surface 3211 of the bottom groove 321 in the three-dimensional vapor chamber device 3, so as to reduce the contact thermal resistance and improve the heat dissipation efficiency of the integrated circuit device A with thermal dissipating package. In practice, when the circuit board 1 does not fit completely and tightly in the bottom groove 321 of the bottom cover 32, the gap between the circuit board 1 and the bottom groove 321 can be filled with thermal gel to make the circuit board 1 and the bottom groove 321 fit more tightly and reduce the heat conduction efficiency from the contact thermal resistance.

Furthermore, in the present embodiment, the bottom cover 32 of the three-dimensional vapor chamber device 3 has a plurality of grooves 322, and a groove rib 3220 is formed between the grooves 322. The groove rib 3220 has a rib surface 3221, and each of the grooves 322 has a groove internal surface 3222 and a groove cavity 3223. The airtight cavity 33 is formed from the base cavity 3111, the groove cavity 3223 and the tubular cavity 3121 when the bottom cover 32 is sealed to the upper cover 31. It is worth noting that in the present embodiment, the shape of the grooves 322 of the bottom cover 32 is square, but it is not limited in practice. The shape and number of the grooves 322 can be designed according to the requirements.

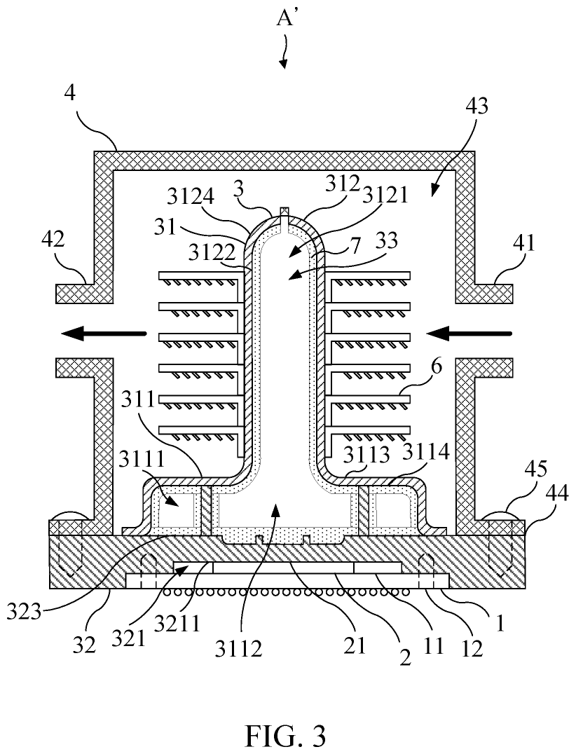

Please refer to FIG. 1 and FIG. 3. FIG. 3 is a cross-sectional diagram illustrating an integrated circuit device A′ with thermal dissipating package according to another embodiment of the present invention. As shown in FIG. 3, the integrated circuit device A′ with thermal dissipating package of the present embodiment differs from the aforementioned embodiment in that the present embodiment further comprises a semi-open case 4. Wherein, the semi-open case 4 has an inlet 41 and an outlet 42. The semi-open case 4 is coupled to the bottom cover 32 of the three-dimensional vapor chamber device 3 to form a heat-exchanging chamber 43 and the upper cover 31 is configured in the heat-exchanging chamber 43. The inlet 41 and the outlet 42 are connected to the heat-exchanging chamber 43. Alternatively, in another embodiment, the inlet 41 and the outlet 42 can be configured on the same side of the semi-open case 4. Furthermore, the integrated circuit device A′ with thermal dissipating package in the present embodiment can be connected to the bottom internal surface 323 of the bottom cover 32 of the three-dimensional vapor chamber device 3 through a joint end 44 of the semi-open case 4, and fastened to the bottom cover 32 with screws 45. It is also possible to use stirring and friction welding to couple the semi-open case 4 to the three-dimensional vapor chamber device 3 to form a heat-exchanging chamber 43, but in practice, the way in which the semi-open case 4 be coupled to the three-dimensional vapor chamber device 3 is not limited to the aforementioned.

In the present embodiment, a cold liquid fluid (not shown) is configured in the heat-exchanging chamber 43, the inlet 41 and the outlet 42 of the integrated circuit device A′ with thermal dissipating package. When the integrated circuit device A′ with thermal dissipating package is operating, the cold liquid fluid can flow from the inlet 41 to the heat-exchanging chamber 43 and then flow to the outlet 42 (as shown by the arrow in FIG. 3). In practice, the cold liquid fluid can be water, acetone, ammonia, methanol, tetrachloroethane, and hydrofluorocarbon chemical refrigerants, but is not limited to the above-mentioned, the cold liquid fluid can also be other fluids that absorb heat and carry away heat energy.

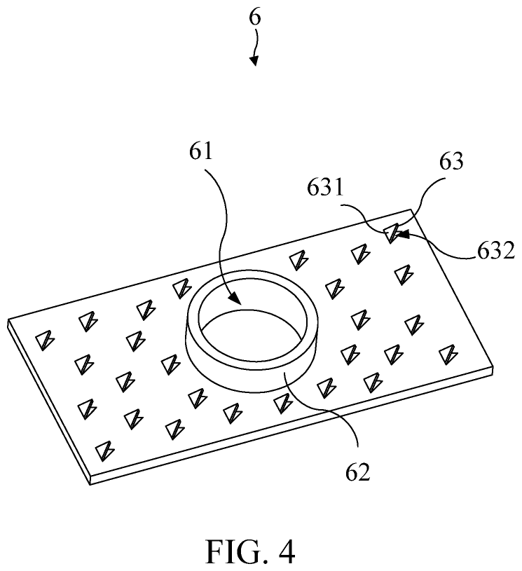

Please refer to FIG. 1 to FIG. 4. FIG. 4 is a structural schematic diagram illustrating a heat dissipation fin 6 in FIG. 3. As shown in FIG. 1 to FIG. 3, the three-dimensional vapor chamber device 3 further comprises a plurality of heat dissipation fins 6, the tube 312 further comprises a condenser area 3124, and the heat dissipation fins 6 are coupled to the condenser area 3124 of the tube 312. In the present embodiment, the three-dimensional vapor chamber device 3 further comprises the plurality of heat dissipation fins 6 coupled on the tube 312, and the tube 312 has the condenser area 3124. The heat dissipation fins 6 are coupled to the condenser area 3124 of the tube 312. The heat dissipation fins 6 have a hole 61 and a protruding structure 62. The diameter of the hole 61 can be slightly smaller than the diameter of the tube 312, so the heat dissipation fins 6 can be disposed on the condenser area 3124 of the tube 312 through the hole 61. The protruding structure 62 is positioned around the edges of the hole 61. In addition, when the plurality of heat dissipation fins 6 are disposed on the tube 312, the protruding structure 62 of the upper heat dissipation fins 6 can hold the lower heat dissipation fins 6, so the plurality of heat dissipation fins 6 can be arranged at a certain spacing. In practice, the number of the heat dissipation fins 6 and the length of the protruding structure 62 can be designed according to the requirements.

As shown in FIG. 1 and FIG. 2, in the present embodiment, when the integrated circuit device A with thermal dissipating package is operating, the heat energy in the gaseous working fluid is transferred to the tube 312, the heat energy can be transferred from the outer surface 3125 of the tube 312 to the heat dissipation fins 6 and the heat energy can be carried away by air cooling technology for heat dissipation. Furthermore, as shown in FIG. 3, the integrated circuit device A′ with thermal dissipating package of the present embodiment carries away the heat energy transferred to the heat dissipation fins 6 by liquid cooling technology for heat dissipation, and increases the contact area between the condenser area 3124 and the cold liquid fluid through the heat dissipation fins 6 disposed on the tube 312 to enhance the heat dissipation efficiency.

Furthermore, as shown in FIG. 4, the heat dissipation fin 6 has a plurality of flow disturbance structures 63. The flow disturbance structure 63 has a spoiler 631 and a spoiler opening hole 632. Please refer to FIG. 3 and FIG. 4. In practice, when the integrated circuit device A′ with thermal dissipating package carries away the heat energy configured on the condenser area 3124, the cold liquid fluid input from the inlet 41 to the heat-exchanging chamber 43 can generate mixed flow in the heat-exchanging chamber 43 through the flow disturbance structures 63 to increase the heat exchange efficiency with the cold liquid fluid in the heat-exchanging chamber 43, and further enhance the whole dissipation efficiency. It is worth noting that in the present embodiment, the shape of the spoiler 631 and the spoiler opening hole 632 of the flow disturbance structure 63 on the heat dissipation fin 6 is triangular, but it is not limited to the aforementioned in practice. In practice, the shape and number of the flow disturbance structure 63 can be designed according to the requirements.

Moreover, as shown in FIG. 1 to FIG. 3, the three-dimensional vapor chamber device 3 of the present embodiment further comprises a porous wick structure 7. The bottom cover 32 of the three-dimensional vapor chamber device 3 further has a bottom internal surface 323, and the porous wick structure 7 is continuously disposed on the upper internal surface 3114, the bottom internal surface 323, the tubular internal surface 3122, the rib surface 3221 of the groove rib 3220 and the groove internal surfaces 3222. In practice, the porous wick structure 7 is disposed by pre-laying a copper-containing powder on the upper internal surface 3114, the bottom internal surface 323, the tubular internal surface 3122, the rib surface 3221 and the groove internal surfaces 3222, and after the heat dissipation fins 6 are disposed on the condenser area 3124 of the tube 312, the porous wick structure 7 is continuously disposed on the upper internal surface 3114, the bottom internal surface 323, the tubular internal surface 3122, the rib surface 3221 and the groove internal surfaces 3222 and the heat dissipation fins 6 are coupled to the condenser area 3124 of the tube 312 simultaneously by the same sintering process, but it is not limited to the aforementioned in practice. In practice, the porous wick structure 7 can be formed by sintering copper-containing powder or by drying, cracking and sintering slurry.

In the present embodiment, the plurality of grooves 322 of the bottom cover 32 in the three-dimensional vapor chamber device 3 can reduce the thermal resistance of heat conduction from the chip 2 to the bottom 32 by reducing the heat conduction distance between the porous wick structure 7 disposed on the bottom cover 32 and the chip 2. Since the three-dimensional vapor chamber device 3 has a complete and continuous porous wick structure 7, the liquid working fluid in the porous wick structure 7 of the condenser area 3124 of the tube 312 can smoothly and quickly return to the porous wick structure 7 of an evaporator area of the bottom cover 32 to make the two-phase flow circulation in the three-dimensional vapor chamber device 3 smooth and further enhance the heat dissipation efficiency.

Furthermore, as shown in FIG. 3, when the integrated circuit device A′ with thermal dissipating package operates, the bottom groove surface 3211 contacted with the chip 2 will absorb the heat energy generated by the heat source. At this time, the liquid working fluid in the porous wick structure 7 of the groove internal surfaces 3222 also absorbs the heat energy and converts to gaseous working fluid, and the gaseous working fluid will carry the heat energy to the condenser area 3124 of the tube 312, and exchange heat with the cold liquid fluid in the heat-exchanging chamber 43. Further, the cold liquid fluid flowing from the inlet 41 of the semi-open case 4 will absorb the heat energy from the condenser area 3124. And, the gaseous working fluid in the three-dimensional vapor chamber device 3 is converted to liquid working fluid at the condenser area 3124, and the liquid working fluid flows back to the porous wick structure 7 disposed on the bottom internal surface 323 of the bottom cover 32 through the porous wick structure 7. Next, the cold liquid fluid with the heat energy flows out from the outlet 42 of the semi-open case 4 to carry away the heat energy generated from the chip 2 for heat dissipation. Therefore, the integrated circuit device A′ with thermal dissipating package in the present invention can directly exchange heat with the cold liquid fluid in the heat-exchanging chamber 43 through the condenser area 3124 of the three-dimensional vapor chamber device 3, so as to enhance the heat dissipation efficiency.

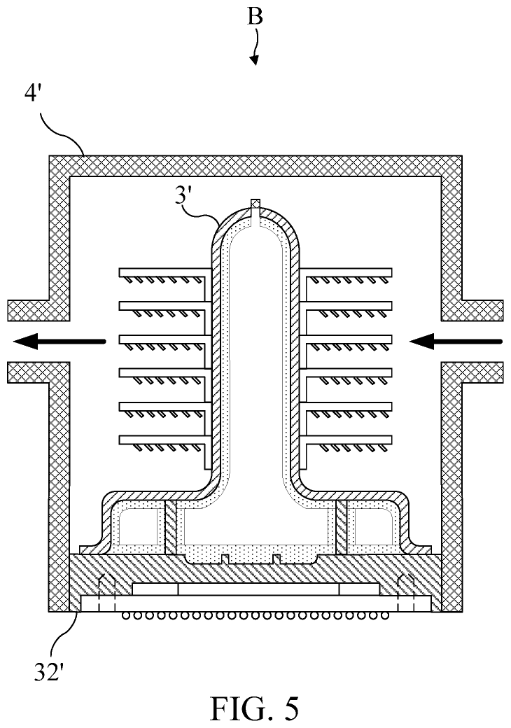

Please refer to FIG. 3 and FIG. 5. FIG. 5 is a cross-sectional diagram illustrating an integrated circuit device B with thermal dissipating package according to another embodiment of the present invention. As shown in FIG. 5, the integrated circuit device B with thermal dissipating package of the present embodiment differs from the aforementioned embodiment in that the three-dimensional vapor chamber device 3′ and the semi-open case 4′ in the present embodiment are coupled by gluing, welding and stirring friction welding to seal the bottom cover 32′ of the three-dimensional vapor chamber device 3′ to the semi-open case 4′. Wherein, the length of the bottom cover 32′ of the three-dimensional vapor chamber device 3′ can be equal to or slightly smaller than the width of the semi-open case 4′, so the semi-open case 4′ and the three-dimensional vapor chamber device 3′ can form the sealed integrated circuit device B with thermal dissipating package. It should be noted that the integrated circuit device B with thermal dissipating package of the present embodiment has substantially the same structure and function as the corresponding element of the aforementioned embodiment, so it will not be described again herein. Furthermore, in practice, the length of the bottom cover 32′ of the three-dimensional vapor chamber device 3′, the width of the semi-open case 4′, and the coupling method between the three-dimensional vapor chamber device 3′ and the semi-open case 4′ are not limited to the aforementioned.

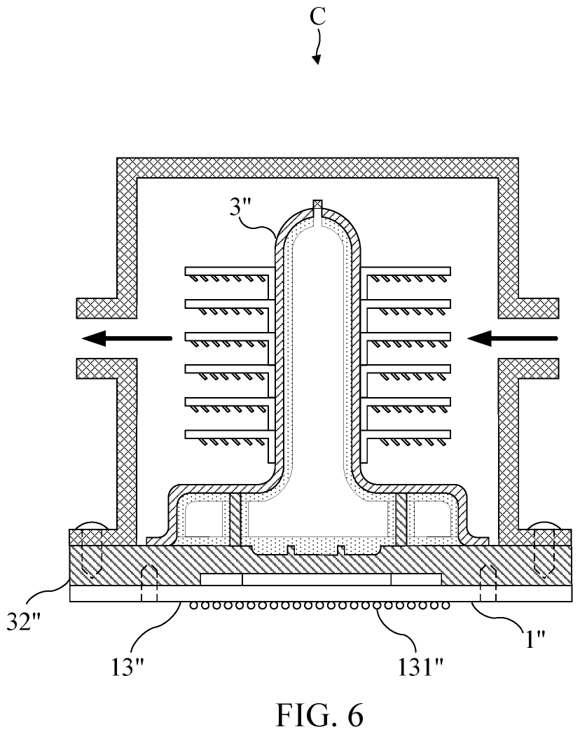

Please refer to FIG. 3 and FIG. 6. FIG. 6 is a cross-sectional diagram illustrating an integrated circuit device C with thermal dissipating package according to another embodiment of the present invention. As shown in FIG. 6, the integrated circuit device C with thermal dissipating package of the present embodiment differs from the aforementioned embodiment in that the length of the circuit board 1″ can be equal to or slightly larger than the length of the bottom cover 32″ of the three-dimensional vapor chamber device 3″. In practice, the circuit board 1″ can be a ball grid array (BGA) board and a plurality of solder balls 131″ are disposed on the lower board surface 13″ of the circuit board 1″. The circuit board 1″ can be a pin grid array (PGA) board and a plurality of solder pins (not shown) are disposed on the lower board surface 13″ of the circuit board 1″. It should be noted that the integrated circuit device C with thermal dissipating package of the present embodiment has substantially the same structure and function as the corresponding element of the aforementioned embodiment, so it will not be described again herein. In practice, the length and type of the circuit board can be determined according to the user's needs. Therefore, the integrated circuit device with thermal dissipating package of the present can be applied to various kinds of circuit boards of different sizes.

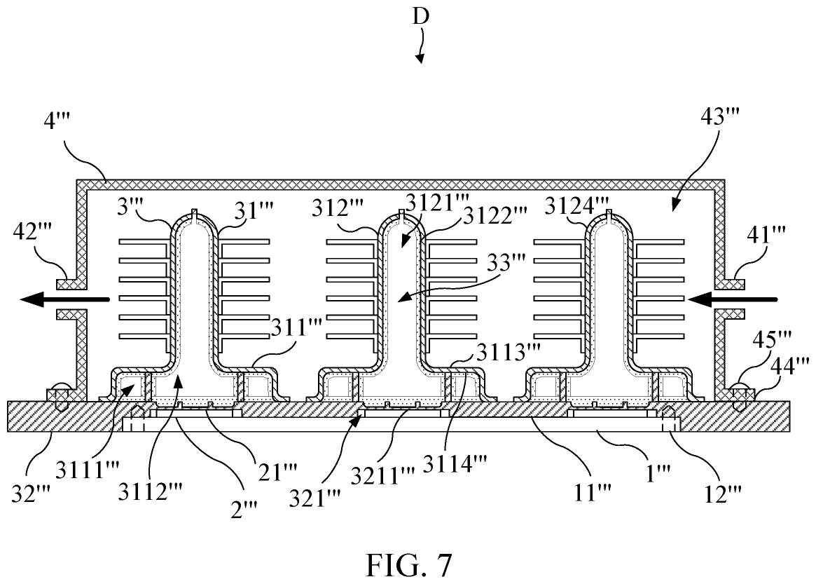

The integrated circuit device with thermal dissipating package of the present can be in other forms in addition to the aforementioned forms. Please refer to FIG. 7. FIG. 7 is a cross-sectional diagram illustrating an integrated circuit device D with thermal dissipating package according to another embodiment of the present invention. The integrated circuit device D with thermal dissipating package in the present embodiment comprises a circuit board 1′″, a plurality of chip 2′″, a plurality of three-dimensional vapor chamber devices 3′″ and a semi-open case 4′″. The circuit board 1′ has an upper board surface 11′″. The plurality of chips is configured on the upper board surface 11″ of the circuit board 1′″, and each of the chips 2′″ has a chip surface 21′″. The plurality of three-dimensional vapor chamber devices 3′ comprises a plurality of upper covers 31′″ and a bottom cover 32′″. Each of upper covers 31′″ comprises a base plate 311′ and a tube 312′″. The base plate 311′″ has a base cavity 3111′″, an opening hole 3112′″, an upper outer surface 3113′″ and an upper internal surface 3114′″. The tube 312′″ has a tubular cavity 3121′″ and a tubular internal surface 3122′″. The tube 312′″ is configured on the upper outer surface 3113′ and located above the opening hole 3112′″ and extended outwardly from the upper outer surface 3113′. The bottom cover 32′″ corresponding to the upper covers 31′″ has a plurality of bottom grooves 321′. Each of the bottom grooves 321′″ has a bottom groove surface 3211′″. An airtight cavity 33′″ is formed from the corresponding tubular cavity 3121′″ and the base cavity 3111′″ respectively, when each of the upper covers 31′″ is sealed to the bottom cover 32′″. Each of the bottom grooves 321′″ is configured to accommodate the chips 2′″. Each of the chip surfaces 21′″ is contacted with the bottom groove surface 3211′″ of the bottom groove 321′″. In practice, the tube 31′ can be directly sealed to the base plate 311′″, and the airtight cavity 33′″ can be formed only by the tube cavity 3121′″.

Furthermore, the integrated circuit device D with thermal dissipating package in the present embodiment can further comprise a semi-open case 4′″. The semi-open case 4′″ has an inlet 41′″ and an outlet 42′″. The semi-open case 4′″ is coupled to the bottom cover 32′″ of the three-dimensional vapor chamber device 3′″ to form a heat-exchanging chamber 43′″ and the upper cover 31′″ is configured in the heat-exchanging chamber 43′″. The inlet 41′″ and the outlet 42′″ are connected to the heat-exchanging chamber 43′″.

As shown in FIG. 7, the integrated circuit device D with thermal dissipating package of the present embodiment differs from the aforementioned embodiment in that the three upper covers 31′″ of the three-dimensional vapor chamber devices 3′″ in the present embodiment can be coupled with the same bottom cover 32′″, can be separately contact the plurality of different chips 2 on the circuit board 1′″, and exchange heat in the same heat-exchanging chamber 43′″. In practice, the plurality of upper covers 31′″ of the three-dimensional vapor chamber devices 3′″ can be arranged in the same heat-exchanging chamber 43′″ in parallel and in other ways. Wherein, the integrated circuit device D with thermal dissipating package in the present embodiment can be connected to the bottom cover 32′″ through a joint end 44′″ of the semi-open case 4′″, and fastened to the bottom cover 32′″ with screws 45′″. It is also possible to use stirring and friction welding to couple the semi-open case 4′″ to the three-dimensional vapor chamber devices 3′″ to form a heat-exchanging chamber 43′″, but in practice, the way in which the semi-open case 4′″ be coupled to the three-dimensional vapor chamber devices 3′″ is not limited to the aforementioned.

When the integrated circuit device D with thermal dissipating package is operating, the cold liquid fluid can flow from the inlet 41′″ to the heat-exchanging chamber 43′″, carry the heat energy from the condenser area 3124′″ disposed on the different upper covers 31′″ through the different upper covers 31′″, and flow from the heat-exchanging chamber 43′″ to the outlet 42′″ (as shown by the arrow in FIG. 7). In practice, the number and arrangement of the upper covers 31′″ can be designed according to the requirements. It should be noted that the integrated circuit device D with thermal dissipating package of the present embodiment has substantially the same structure and function as the corresponding element of the aforementioned embodiment, so it will not be described again herein. Therefore, in the integrated circuit device D with thermal dissipating package of the present invention, the plurality of upper covers of the three-dimensional vapor chamber device can be coupled with the same bottom cover to be contacted with the plurality of heat sources or the same heat source, and dissipate heat in the same heat exchanger, so as to enhance the whole heat dissipation efficiency of the integrated circuit device with thermal dissipating package. Furthermore, in another embodiment (not shown), an integrated circuit device with thermal dissipating package can not include the semi-open case 4′″ and the cold liquid fluid disposed in the heat-exchanging chamber 43′″, the inlet 41′″ and the outlet 42′″. In practice, the present embodiment can dissipate heat by air-cooling technology.

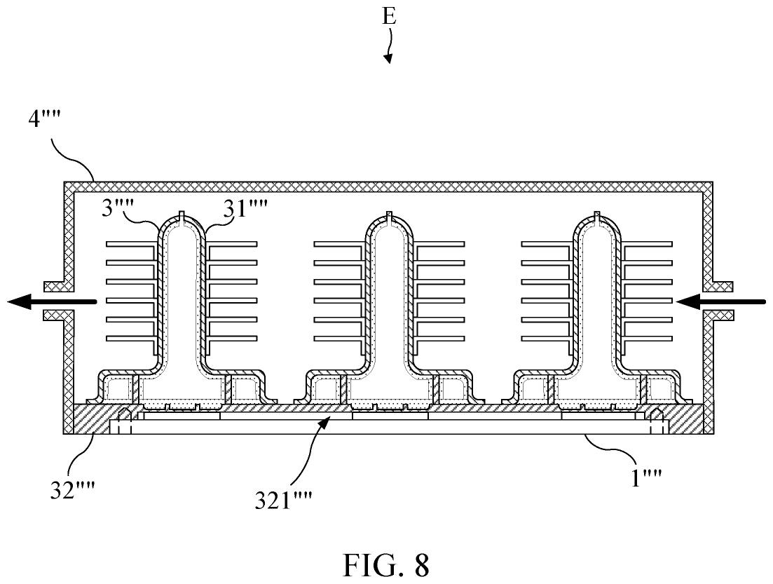

Please refer to FIG. 7 and FIG. 8. FIG. 8 is a cross-sectional diagram illustrating an integrated circuit device E with thermal dissipating package according to another embodiment of the present invention. The integrated circuit device E with thermal dissipating package of the present embodiment differs from the aforementioned embodiment in that a three-dimensional vapor chamber device 3″ of the present embodiment comprises a single bottom cover 32″, and has only a single bottom groove 321″″ in contrast to a plurality of upper covers 31″″. In practice, when the circuit board 1“ ” does not fit completely and tightly in the bottom groove 321″″ of the bottom cover 32″, the gap between the circuit board 1″″ and the bottom groove 321″″ can be filled with thermal gel to make the circuit board 1″″ and the bottom groove 321″″ fit more tightly and reduce the heat conduction efficiency from the contact thermal resistance. In addition, the length of the bottom cover 32″ of the three-dimensional vapor chamber device 3″ can be equal to or slightly smaller than the width of the semi-open case 4″, so the semi-open case 4″ and the three-dimensional vapor chamber device 3″ can form the sealed integrated circuit device E with thermal dissipating package. In another embodiment (not shown), the length of the circuit board 1″″ can be equal to or slightly larger than the length of the bottom cover 32″ of the three-dimensional vapor chamber device 3″. In practice, the length and type of the circuit board can be determined according to the user's needs. Therefore, the integrated circuit device with thermal dissipating package of the present can be applied to various kinds of circuit boards of different sizes. It should be noted that the integrated circuit device E with thermal dissipating package of the present embodiment has substantially the same structure and function as the corresponding element of the aforementioned embodiment, so it will not be described again herein.

In summary, the present invention provides an integrated circuit device with thermal dissipating package, integrating the circuit board with the chip and the heat dissipator in an integrated circuit device. The integrated circuit device with thermal dissipating package in the present invention can reduce the thermal resistances between the chip and the heat dissipator in the integrated circuit packaging of the prior art by contacting the chip surface with the bottom groove surface of the three-dimensional vapor chamber device. Moreover, by directly contacting with the cold liquid fluid in the heat-exchanging chamber through the condenser area of the three-dimensional vapor chamber device with two-phase flow circulation for heat exchange to enhance the heat dissipation efficiency of the integrated circuit device with thermal dissipating package of the present invention. In addition, the screws in the integrated circuit device with thermal dissipating package of the present invention can fix the circuit board with the chip to the lower case surface. The screws can increase the contact pressure between the chip and the bottom groove surface of the bottom cover in the three-dimensional vapor chamber device, so as to reduce the contact thermal resistance and improve the heat dissipation efficiency of the integrated circuit device. Furthermore, the plurality of grooves of the bottom cover in the integrated circuit device with thermal dissipating package of the present invention can reduce the thermal resistance of heat conduction from the heat source to the porous wick structure disposed on the bottom internal surface of the bottom cover by reducing the heat conduction distance between the porous wick structure disposed on the bottom cover and the heat source, while taking into account the structural strength of the bottom cover, so as to enhance the heat conduction efficiency. Furthermore, the integrated circuit device with thermal dissipating package of the present invention can increase the contact area between the condenser area and the cold liquid fluid through the heat dissipation fins disposed on the tube to enhance the heat dissipation efficiency; and increase the heat exchange efficiency with the cold liquid fluid in the heat-exchanging chamber through the flow disturbance structure disposed on the heat dissipation fins generates mixed flow in the heat-exchanging chamber, so as to increase the heat dissipation efficiency. In the integrated circuit device with thermal dissipating package of the present invention, the plurality of upper covers of the three-dimensional vapor chamber device can be coupled with the same bottom cover to be contacted with the plurality of heat sources or the same heat source, and dissipate heat in the same heat exchanger, so as to enhance the whole heat dissipation efficiency of the present invention. Compared to the prior art, the integrated circuit device with thermal dissipating package of the present invention integrates the circuit board with the chip and the heat dissipator in an integrated circuit device to reduce the redundant interface and thermal resistance between the integrated circuit device and the heat dissipator, so as to enhance the whole heat dissipation efficiency of the integrated circuit device with thermal dissipating package.

With the examples and explanations mentioned above, the features and spirits of the invention are hopefully well described. More importantly, the present invention is not limited to the embodiment described herein. Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An integrated circuit device with thermal dissipating package, comprising:
a circuit board, having an upper board surface;
a chip, configured on the upper board surface of the circuit board, the chip having a chip surface; and
a three-dimensional vapor chamber device, comprising:
an upper cover, comprising a base plate and a tube, the base plate having an opening hole, an upper outer surface and an upper internal surface, the tube having a tubular cavity and a tubular internal surface, and the tube being configured on the upper outer surface and located above the opening hole and extended outwardly from the upper outer surface; and
a bottom cover, corresponding to the upper cover and having a bottom groove, the bottom groove having a bottom groove surface, an airtight cavity formed from the tubular cavity when the bottom cover is sealed to the upper cover, and the bottom groove configured to accommodate the chip, the chip surface of the chip contacted with the bottom groove surface of the bottom groove.

2. The integrated circuit device with thermal dissipating package of claim 1, further comprising a semi-open case, having an inlet and an outlet, the semi-open case coupled to the bottom cover of the three-dimensional vapor chamber device to form a heat-exchanging chamber and the upper cover be configured in the heat-exchanging chamber, and the inlet and the outlet connected to the heat-exchanging chamber, the bottom groove configured to accommodate the circuit board with the chip, and the circuit board having a plurality of locking holes, and the circuit board with the chip locked to the bottom groove surface of the bottom groove by a plurality of screws.

3. The integrated circuit device with thermal dissipating package of claim 2, wherein a cold liquid fluid is configured in the heat-exchanging chamber, the inlet and the outlet, and the cold liquid fluid is selected from the group consisting of water, acetone, ammonia, methanol, tetrachloroethane, and hydrofluorocarbon chemical refrigerants.

4. The integrated circuit device with thermal dissipating package of claim 1, wherein the bottom cover has a plurality of grooves, and a groove rib is formed between the grooves, the groove rib has a rib surface, and each of the grooves has a groove internal surface and a groove cavity.

5. The integrated circuit device with thermal dissipating package of claim 4, further comprising a porous wick structure, the bottom cover having a bottom internal surface, the porous wick structure continuously disposed on the upper internal surface, the bottom internal surface, the tubular internal surface, the rib surface of the groove rib and the groove internal surfaces.

6. The integrated circuit device with thermal dissipating package of claim 5, wherein the three-dimensional vapor chamber device further comprises a plurality of heat dissipation fins, the tube further comprises a condenser area, and the heat dissipation fins coupled to the condenser area of the tube.

7. The integrated circuit device with thermal dissipating package of claim 6, wherein the porous wick structure is disposed by pre-laying a copper-containing powder on the upper internal surface, the bottom internal surface, the tubular internal surface, the rib surface and the groove internal surfaces, and after the heat dissipation fins are disposed on the condenser area of the tube, the porous wick structure is continuously disposed on the upper internal surface, the bottom internal surface, the tubular internal surface, the rib surface and the groove internal surfaces and the heat dissipation fins are coupled to the condenser area simultaneously by the same sintering process.

8. The integrated circuit device with thermal dissipating package of claim 1, wherein the tube further has a top end having a sealed structure, the base plate further has a base cavity, and the airtight cavity is formed from the base cavity and the tubular cavity when the bottom cover is sealed to the upper cover.

9. The integrated circuit device with thermal dissipating package of claim 8, wherein the sealed structure is formed by pre-setting a liquid injection port at the top end, and injecting the working fluid into the airtight cavity through the liquid injection port, and then sealing the liquid injection port.

10. An integrated circuit device with thermal dissipating package, comprising:
a circuit board, having an upper board surface;
a plurality of chips, configured on the upper board surface of the circuit board, each of the chips having a chip surface; and
a plurality of three-dimensional vapor chamber devices, comprising:
a plurality of upper cover, each of the upper covers comprising a base plate and a tube, the base plate having an opening hole, an upper outer surface and an upper internal surface, the tube having a tubular cavity and a tubular internal surface, and the tube being configured on the upper outer surface and located above the opening hole and extended outwardly from the upper outer surface; and
a bottom cover, corresponding to the upper covers and having a bottom groove, the bottom groove having a bottom groove surface, an airtight cavity formed from the corresponding tubular cavity when the bottom cover is sealed to the upper covers, and the bottom groove configured to accommodate the chips, each of the chip surfaces contacted with the bottom groove surface of the bottom groove.
